(19) United States
(12) Patent Application Publication
(10) Pub. No.: US 2025/0258196 A1
(43) Pub. Date: Aug. 14, 2025

(54) Probe head having vertically embedded components in the printed circuit board

(71) Applicant: FormFactor, Inc., Livermore, CA (US)

(72) Inventors: January Kister, Portola Valley, CA (US); Todd Swart, San Antonio, TX (US); Miguel B. Enteria, Hayward, CA (US)

(21) Appl. No.: 19/048,770

(22) Filed: Feb. 7, 2025

Related U.S. Application Data
(60) Provisional application No. 63/551,312, filed on Feb. 8, 2024.

(51) Int. Cl. G01R 1/073; H05K 1/11; H05K 1/14; H05K 1/18

(52) U.S. Cl. CPC G01R 1/07314; H05K 1/115; H05K 1/142; H05K 1/185; H05K 2201/10378; H05K 2201/10734

(57) ABSTRACT

Passive electrical components (e.g., capacitors) are vertically embedded in the printed circuit board of the probe head. The resulting configuration ensures the components are close to their corresponding probes by making use of the component real estate of the printed circuit board, and by having relatively short vertical connections to the probes (via the space transformer). As a result, improved compensation of probe inductance is provided for probe arrays.

### CROSS REFERENCE TO RELATED APPLICATIONS

This application claims priority from U.S. Provisional Patent Application 63/551,312 filed Feb. 8, 2024, which is incorporated herein by reference.

### GOVERNMENT SPONSORSHIP

None.

### FIELD OF THE INVENTION

This invention relates to making temporary electrical contact to a device/circuit/wafer under test with a probe array.

### BACKGROUND

Arrays of probes are often used to make temporary electrical contact to a device under test. Such probe arrays are often configured as a probe head that includes the probes, a space transformer and a printed circuit board (PCB). The purpose of the space transformer is to match the fine pitch typical of the probe array to a larger pitch that is compatible with printed circuit board technology. The printed circuit board connects the space transformer to the rest of the test equipment.

When such a probe head is used for testing high power chips that draw high switching currents, such currents can cause fluctuations in ground planes due to dV=L*Di/dT (i.e., inductance) disturbing chip functioning. To minimize such effects, it is often necessary to add closely positioned and connected to power and ground planes capacitors to compensate for the inductance of probes. Conventionally, such capacitors are disposed on the periphery of the space transformer (e.g., 110 on FIG. 1), but there is limited space for components there, and ideally the capacitors should be as close to the probes as possible.

Accordingly, it would be an advance in the art to provide probe heads having an improved configuration of these capacitors.

### SUMMARY

In this work, capacitors (or other passive electrical components) are vertically embedded in the printed circuit board of the probe head. The resulting configuration ensures the capacitors are close to their corresponding probes by making use of the component real estate of the printed circuit board, and by having relatively short vertical connections to the probes (via the space transformer).

Several variations are possible. Different layers of the printed circuit board can have different size components. Two or more printed circuit boards having embedded components can be stacked. Stacks of multiple printed circuit boards can have some printed circuit boards with embedded components and other printed circuit boards without embedded components.

Further variations include: an interposer for making vertical connections between printed circuit boards, a motherboard/daughterboard configuration, and dual lamination between a main printed circuit board and a sub-printed circuit board.

A mechanical stiffener on top of the last (top) PCB can be utilized as a heat absorbing layer and/or thermal heat exchanger connected to heat pipes carrying energy to/from a heat diffuser positioned away from the Probe Card/Tester.

### BRIEF DESCRIPTION OF THE DRAWINGS

FIG. 1 shows a first exemplary embodiment.

FIG. 2 shows a second exemplary embodiment.

FIG. 3 shows a third exemplary embodiment.

FIG. 4 shows a fourth exemplary embodiment.

FIG. 5 shows a fifth exemplary embodiment.

FIG. 6 shows a sixth exemplary embodiment.

FIG. 7 shows a seventh exemplary embodiment.

FIG. 8 shows an eighth exemplary embodiment.

FIG. 9 shows a ninth exemplary embodiment.

### DETAILED DESCRIPTION

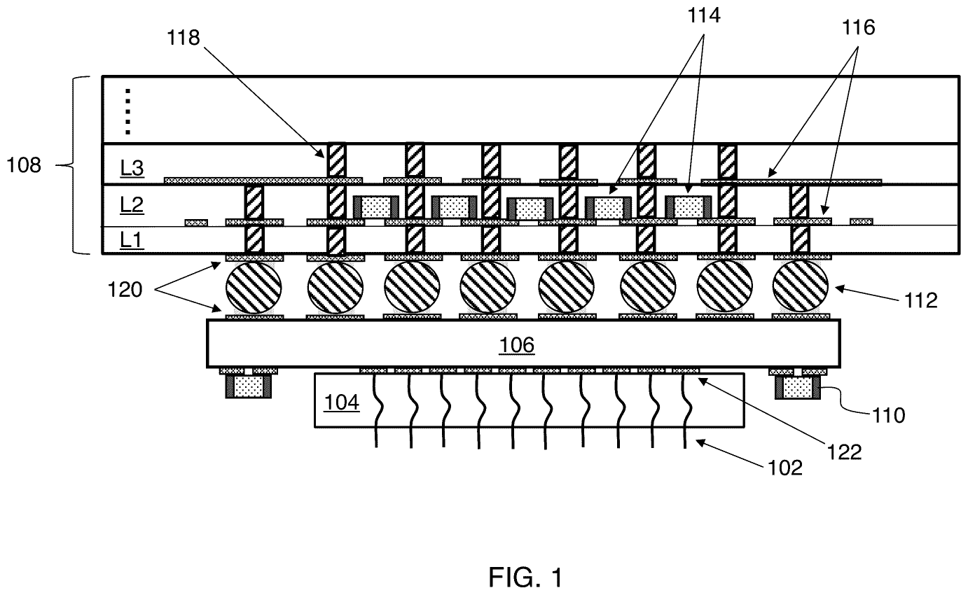

FIG. 1 shows a first exemplary embodiment. Here probes 102 are included in probe head 104 and make electrical contact to space transformer 106 via space transformer contacts 122. Printed circuit board 108 includes layers L1, L2, L3 . . . , and in this example layer L2 includes embedded passive components 114 (e.g., capacitors). Printed circuit board 108 also includes conductive contact pads/planes/traces 116 (e.g., fabricated in copper metal or any other suitable conductor) and vertical vias 118. It is known in the art how to make multi-layer printed circuit boards having vias 118 and conductive features 116 between its layers. In this example, contact between space transformer 106 and printed circuit board 108 is via ball grid array (BGA) 112 and BGA contact pads 120. Such BGA contact pads can be gold-plated. Optionally, passive components 110, such as capacitors, can be mounted on the probe side of space transformer 106, as shown. As shown, contacts/traces 116 can combine with vias 118 to electrically connect passive components 114 to the probe array via space transformer 106.

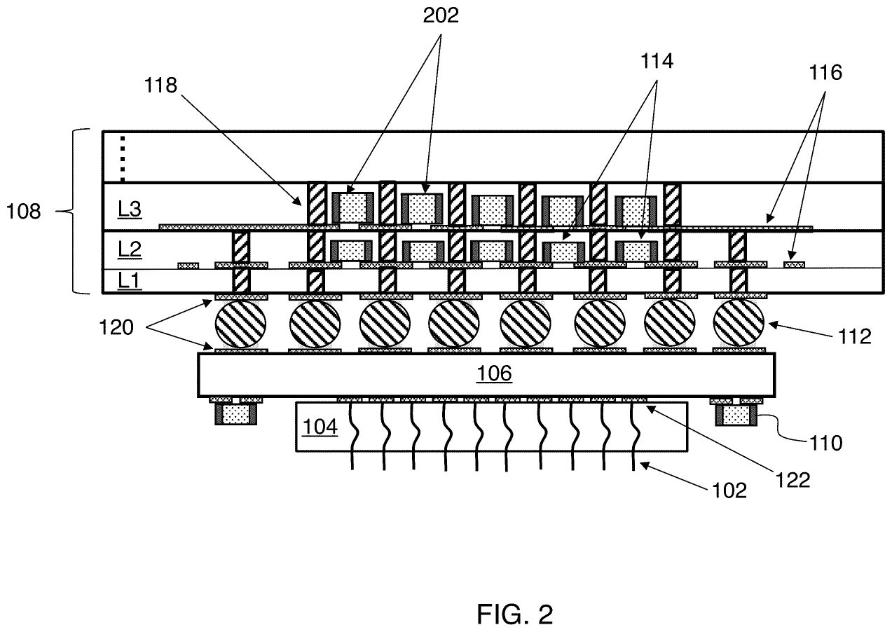

FIG. 2 shows a second exemplary embodiment. This example is similar to the example of FIG. 1, except that passive electrical components are included in two layers (components 202 in layer L3 and components 114 in layer L2). One reason for such an approach is if some passive components are thicker than other passive components. In such a case, the thicker components can be disposed in a thicker layer of the printed circuit board, as shown.

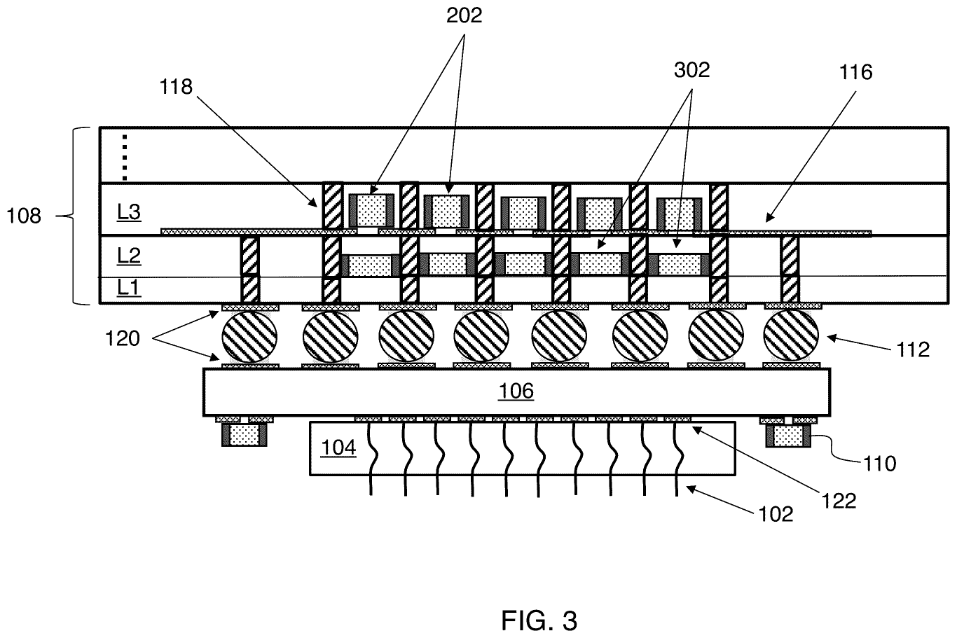

FIG. 3 shows a third exemplary embodiment. This example is similar to the example of FIG. 2, except that passive electrical components 302 in layer L2 make direct lateral contact to vias 118. This can advantageously simplify the design. For example, as shown on FIG. 3, no conductive traces etc. are needed on the bottom surface of L2 to make contact to passive components 302.

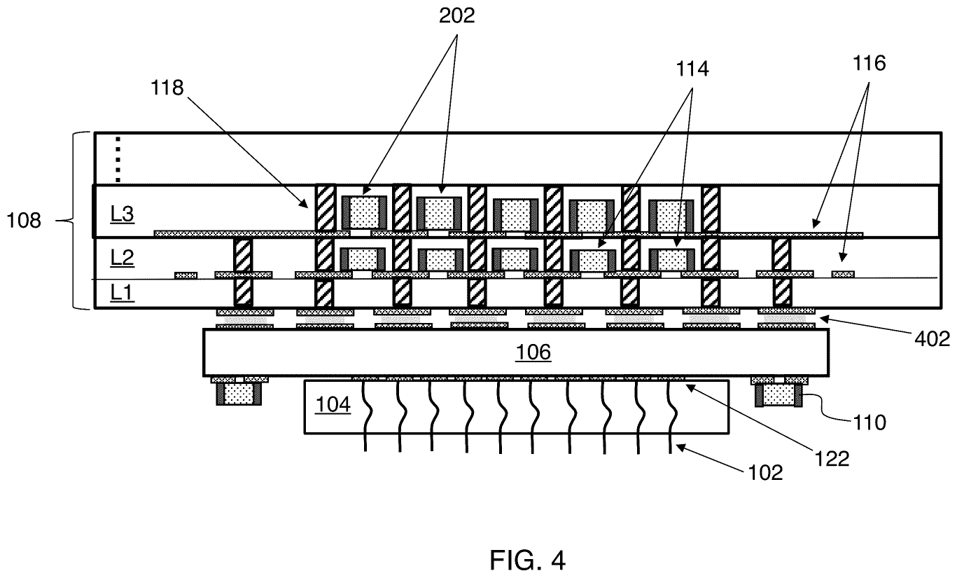

FIG. 4 shows a fourth exemplary embodiment. This example is similar to the example of FIG. 2, except that instead of connecting printed circuit board 108 to space transformer 106 with a ball grid array, these connections are made via a conductive paste or lamination 402.

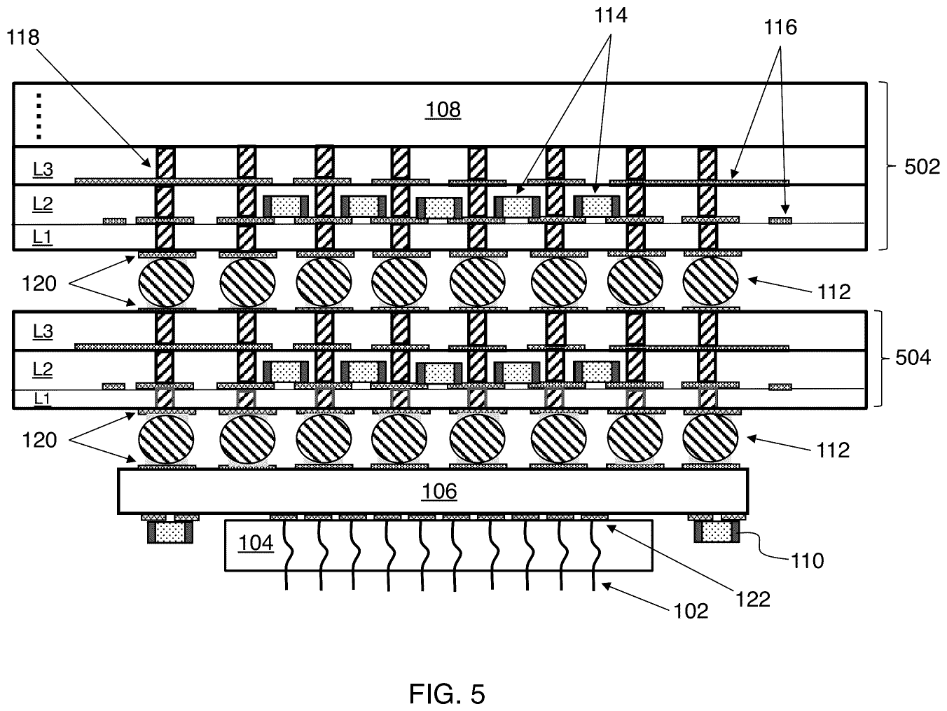

FIG. 5 shows a fifth exemplary embodiment. This example is similar to the example of FIG. 1, except that two printed circuit boards 502 and 504 are stacked, and connected to each other via a ball grid array 112. Here printed circuit boards 502 and 504 each include embedded passive components as described above. Any number of printed circuit boards can be stacked in this way.

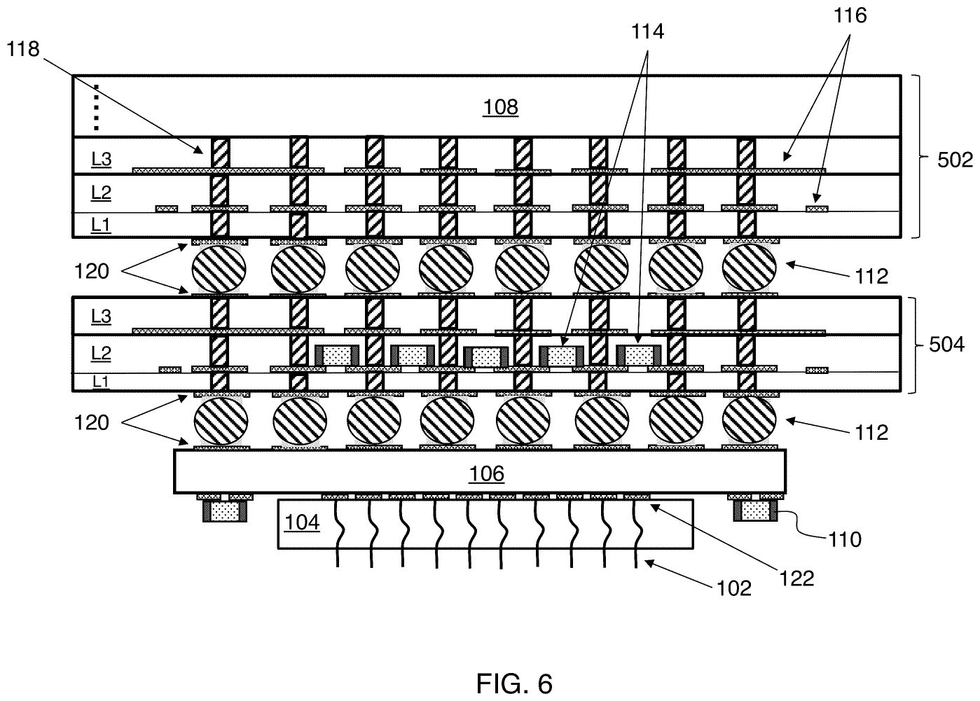

FIG. 6 shows a sixth exemplary embodiment. This example is similar to the example of FIG. 5, except that printed circuit board 502 includes no embedded components. This case could apply to applications where it is advantageous to separate a high density printed circuit board (e.g., for input/output for signals, including embedded components) from a printed circuit board with power and ground planes (but not including embedded components).

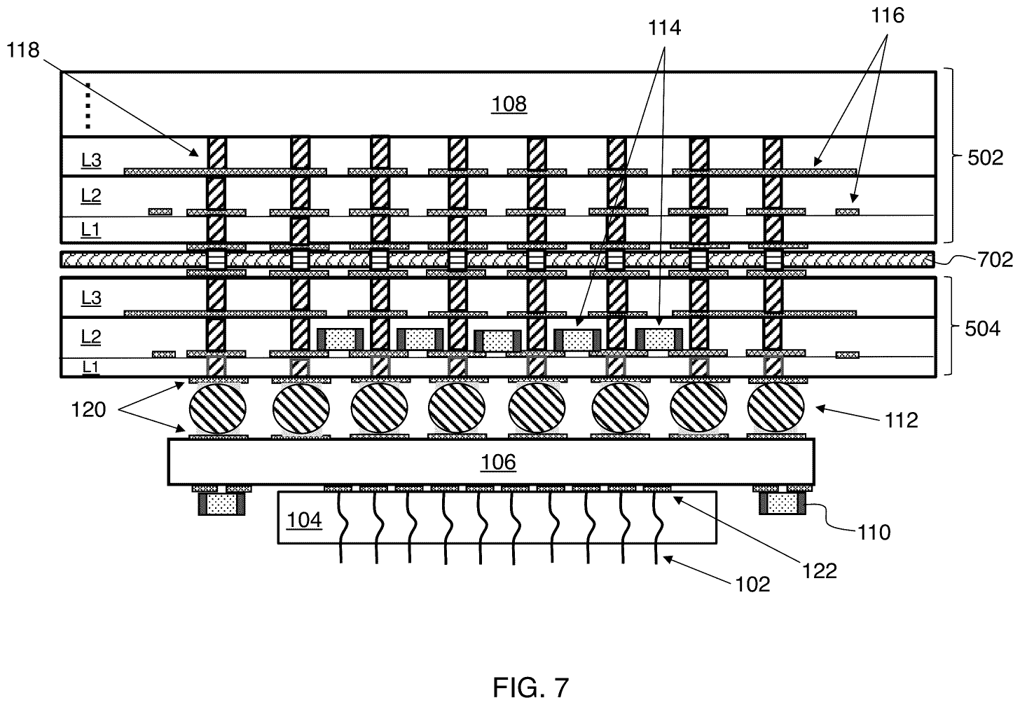

FIG. 7 shows a seventh exemplary embodiment. This example is similar to the example of FIG. 6, except that printed circuit boards 502 and 504 are connected via an interposer layer 702 instead of a ball grid array. The interposer can be a contactor that can be made from springy metal or metallized probes, held in location by an electrically insulating but thermally conductive “probe carrier”. The carrier would preferably be made out of highly heat conductive material to help conduct heat from the middle of the PCB to the edges of the PCB. Thermally conductive metal vias in the PCBs could carry the heat to a heat exchanger on the top or sides of the PCBs.

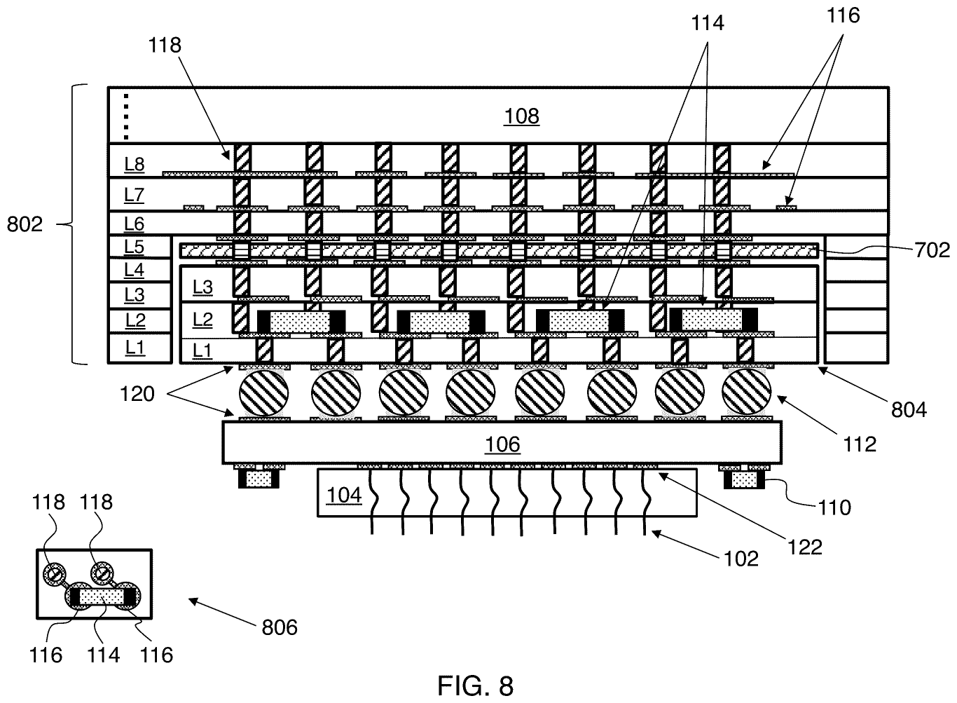

FIG. 8 shows an eighth exemplary embodiment. This example is similar to the example of FIG. 7, except that the two printed circuit boards are configured as a mother board 802 and a replaceable daughter board 804. Another feature of this example is the use of offset traces to more efficiently pack passive components into the available printed circuit board real estate. Inset 806 shows a schematic top view corresponding to the side view shown in the main figure. Here it is apparent that vias 118 shown on FIG. 8 (main part) as being covered by components 114 are actually behind and not touching components 114 (as shown on inset 806). Traces 116 make the indicated electrical connections between vias 118 and passive components 114.

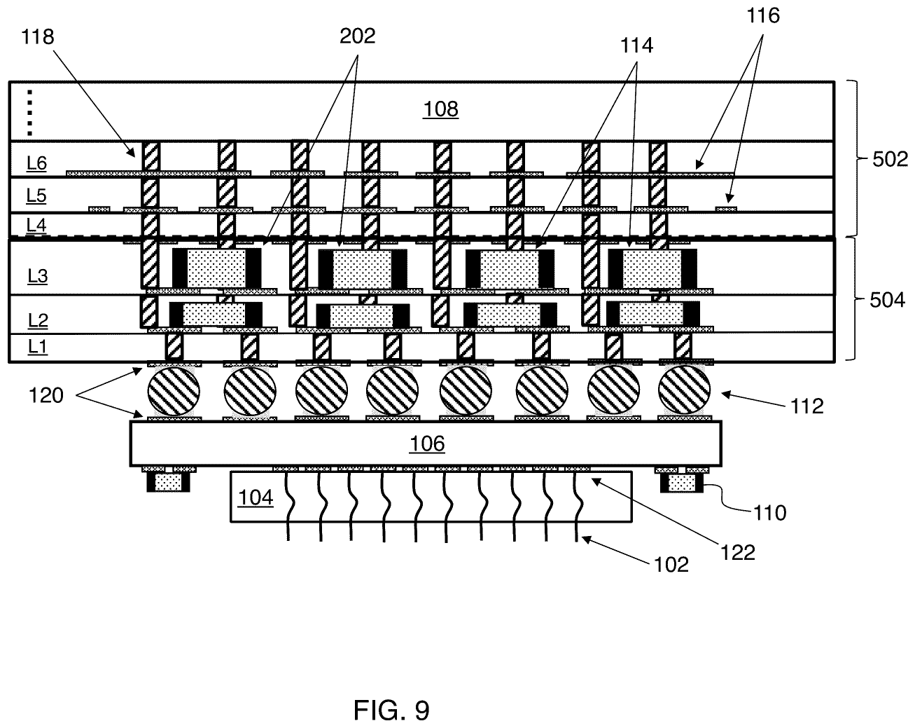

FIG. 9 shows a ninth exemplary embodiment. This example is similar to the example of FIG. 8, except that the two printed circuit boards are configured as a main printed circuit board 502 dual-laminated to a sub-board 504.

1. A probe head comprising:
an array of probes configured to make temporary electrical contact to a device under test;
a space transformer electrically connected to base ends of probes of the probe array at a first surface of the space transformer;
a first printed circuit board electrically connected to a second surface of the space transformer opposite the first surface of the space transformer; and
two or more first passive electrical components embedded within the first printed circuit board and electrically connected to corresponding probes of the probe array with first electrical paths that include vertical vias in the first printed circuit board.

2. The probe head of claim 1, wherein at least one of the first passive electrical components is directly connected to side surfaces of the vertical vias.

3. The probe head of claim 1, further comprising one or more DUT-side passive components disposed on the first surface of the space transformer and electrically connected to one or more of the probes.

4. The probe head of claim 1, wherein the first printed circuit board includes two or more insulating layers, wherein each of the insulating layers has a corresponding metallization pattern on at least one of its surfaces.

5. The probe head of claim 4, wherein at least one of the metallization patterns includes offset connections to a selected at least one of the first passive electrical components to avoid interference between the vertical vias and the selected first passive electrical components.

6. The probe head of claim 4, wherein the two or more first passive electrical components are all embedded in a selected one of the insulating layers.

7. The probe head of claim 4, wherein the two or more first passive electrical components are embedded in a selected two or more of the insulating layers, and wherein thicker passive electrical components are embedded in thicker insulating layers.

8. The probe head of claim 1, further comprising a second printed circuit board electrically connected to the first printed circuit board and opposite the space transformer.

9. The probe head of claim 8, further comprising two or more second passive electrical components embedded within the second printed circuit board and electrically connected to the first printed circuit board with second electrical paths that include vertical vias in the second printed circuit board.

10. The probe head of claim 8, wherein the second printed circuit board is electrically connected to the first printed circuit board via a ball grid array.

11. The probe head of claim 8, wherein the second printed circuit board is laminated to the first printed circuit board.

12. The probe head of claim 8, further comprising an interposer disposed between the first printed circuit board and the second printed circuit board, wherein the interposer is configured to make electrical connections between the first printed circuit board and the second printed circuit board.

13. The probe head of claim 8, wherein the first printed circuit board is configured as a replaceable daughter card that fits within the second printed circuit board.
